(19) United States
(12) Patent Application Publication
(10) Pub. No.: US 2005/0138532 A1
(43) Pub. Date: Jun. 23, 2005

(54) Apparatus and method for concealing errors in a frame

(76) Inventor: Young-O Park, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(21) Appl. No.: 10/934,446

(22) Filed: Sep. 7, 2004

(30) Foreign Application Priority Data
Sep. 6, 2003 (KR) 2003-62363

(51) Int. Cl. H04B 1/66; H03M 13/00

(52) U.S. Cl. 714/776

(57) ABSTRACT

An apparatus and method for concealing an error in a frame using multiple frames are provided. A frame decoder decodes a bit stream of a received frame, and determines whether there is a defective macro block in the decoded frame. A buffer stores at least two previous frames decoded by the frame decoder, and outputs a decoded current frame according to a control signal. An error corrector, if there is a defective macro block in the current frame, searches for a candidate macro block most similar to the defective macro block in the current frame from the at least two previous frames stored in the buffer and restores the defective macro block by applying error variance-based weights to the respective macro blocks. A combining/outputting unit replaces the defective macro block in the current frame with the restored macro block.

### PRIORITY

This application claims the benefit under 35 U.S.C. § 119(a) to an application entitled “Apparatus and Method for Concealing Errors in a Frame” filed in the Korean Intellectual Property Office on Sep. 6, 2003 and assigned Serial No. 2003-62363, the entire contents of which are incorporated herein by reference.

### BACKGROUND OF THE INVENTION

1. Field of the Invention

The present invention relates generally to an apparatus and method for concealing errors in a frame. In particular, the present invention relates to an apparatus and method for concealing errors in a frame for a moving image.

2. Description of the Related Art

Usually, in order to make still images appear to be moving, a large number of frames are continuously displayed for a short time. In this case, one frame corresponds to one still picture. In order to show a moving image using a plurality of still pictures, it is necessary to display a large number of frames for a short time. To accomplish this, high-speed data processing is required, because each frame has a large volume of data and such frames must be continuously provided for a short time.

Research has been conducted on a frame compression technique for processing a moving image with a small amount of data. Based on such research, H.263, H.263+, Moving Picture Experts Group 1 (MPEG-1), MPEG-2, MPEG-4, and H.26L frame compression techniques for a moving image have been enacted as international standards in the international standardization organization. Because data created with such compression techniques has a high compression rate, it can be easily transmitted even in a system having a channel whose bandwidth is limited.

However, at a high data compression rate, if an error occurs in transmission data, data restoration performance is seriously deteriorated. In order to solve the performance deterioration problem due to the occurrence of the error, many attempts are being made to perform coding such that moving-image data has possible maximum robustness against a transmission error. There is a conventional frame error concealment technique used for providing robustness against an error in moving-image data. The “frame error concealment technique” used herein refers to a method for minimizing an influence of an error when an image decoder receives a defective frame (or a frame having an error) and decodes its original frame.

Now, a description will be made of a currently-available frame error concealment technique. The frame error concealment technique can be classified into a single-frame error concealment technique and a multi-frame error concealment technique according to the number of frames which are used to restore lost data. The single-frame error concealment technique is used when the number of frames which are used for data restoration is one, and the multi-frame error concealment technique is used when the number of frames which are used for data restoration is two or more.

Several methods have been proposed for frame error concealment based on calculating a motion vector of a lost macro block. A first method uses one previously-received frame, and a second method uses two or more previously-received frames. The first method can be subdivided into three methods according to a method of using a previously-received frame (hereinafter referred to as a “previous frame”). A brief description of the three methods will be made herein below.
(1) A first method fetches from a previous frame the same macro block as a defective macro block (or a macro block having an error) in a currently-received frame.
(2) A second method restores a lost moving vector using a middle value or an average value between motion vectors near a lost macro block of a currently-received frame.
(3) A third method fetches a macro block most similar to a current frame by estimating neighboring pixel values of a lost macro block from one previously-received frame.

In this connection, the multi-frame error concealment technique also fundamentally restores a motion vector using the methods used in the single-frame error concealment technique. However, the multi-frame error concealment technique searches not one previous frame but two or more previous frames for a lost macro block.

A description will now be made of a structure of a frame and a technique for concealing errors in the frame.

FIG. 1 is a diagram illustrating a one-frame structure of a general frame. In an example of FIG. 1, one frame comprises a plurality of macro blocks. Reference numeral 100 represents one frame. The frame varies in size according to a service having a specific aspect ratio. As illustrated in FIG. 1, one frame includes N macro blocks in each row. That is, a frame of FIG. 1 comprises macro locks 101, 102, . . . , 10N in a first row, macro blocks 111, 112, . . . , 11N in a second row, and macro blocks (not shown) in follows rows. Generally, each macro block can become a coding unit.

Such macro blocks comprise one frame. Each of the macro blocks comprise a set of pixels, and for example, 12×12 pixels can comprise one macro block. As illustrated in FIG. 1, for example, the macro block 11N comprises 144 pixels 11N-(1,1), . . . , 11N-(1,12), 11N-(2,1), . . . , 11N-(2,12), . . . . Because a method for coding the pixels is disclosed in detailed in the standards and is known in the art, a detailed description thereof will not be made herein.

With reference to FIG. 2, a description will now be made of a method for concealing errors using a single frame having the structure of FIG. 1. FIG. 2 is a diagram illustrating a method for concealing errors in a received frame using a single frame according to the prior art.

The single-frame error concealment technique searches only one previously-received frame when detecting a portion corresponding to a currently-received defective macro block from a previously-received frame. For example, as illustrated in FIG. 2, if a lost macro block 211 is found in a k^{th} currently-received frame 210, a previously-received frame 200 is searched for a portion corresponding to the lost macro block 211. In this case, although the entire frame can be searched, typically only a particular region is searched.

The search is made on a previous frame. That is, FIG. 2 illustrates a method for searching a search region 201 in a previous frame #(k-1) of a current frame #k. The search region 201 can comprise several macro blocks. In this case, the nearest macro blocks are searched for by matching macro blocks in the previous frame 200 with macro blocks in the current frame 210. Generally, however, a region where pixels most similar to the pixels of a defective frame are concentrated is searched for in the search region 201. The pixels in the region where the most similar pixels are concentrated comprise one macro block, and the macro block replaces a corresponding macro block in the current frame via macro block replaced 204.

In the method for concealing errors using only one frame, because the number of frames is limited to 1, the probability of searching for a correct macro block is decreased in the edge of a screen or a region where an object appears again after its disappearance.

Next, with reference to FIG. 3, a description will be made of a method for concealing errors using multiple frames. FIG. 3 is a diagram illustrating a method for concealing errors in a received frame using multiple frames according to the prior art.

Assuming that a current point is a k^{th} point, if errors occur in a currently-received frame 350, the multi-frame error concealment technique conceals the errors in the current frame using two or more previously-received frames. In FIG. 3, the multi-frame error concealment technique uses a frame 340 at a (k-1)^{th} point, a frame 330 at a (k-2)^{th} point, a frame 320 at a (k-3)^{th} point, and a frame 310 at a (k-4)^{th} point. The previously-received frames 310, 320, 330 and 340 also have their own search regions which are similar to the search region 201 described in conjunction with FIG. 2.

The most similar macro blocks 311, 321, 331 and 341 are searched for in the search regions of the respective frames 310, 320, 330 and 340. The searches are also made in the method described in connection with FIG. 2. In the case of FIG. 3, because 4 frames are used, an average of pixel values of the most similar macro block in each frame is calculated and then applied to a defective macro block 351. In this manner, errors in a frame can be concealed.

The multi-frame error concealment technique is superior to the single-frame error concealment technique in restoration ratio. However, in order for the multi-frame error concealment technique to be used in H.263+ or MPEG-4, it is necessary to modify a structure of an existing decoder by, for example, increasing the capacity of a memory. In addition, the multi-frame error concealment technique restores a macro block to be concealed, by simply calculating an average of pixel values of a candidate macro block selected from each frame. Therefore, although the multi-frame error concealment technique can be slightly superior to the single-frame error concealment technique in error concealment performance, information on the incorrect macro blocks can be included undesirably in a macro block which is restored with the same weight.

### SUMMARY OF THE INVENTION

It is, therefore, an object of the present invention to provide an apparatus and method for efficiently concealing errors occurring in a frame.

It is another object of the present invention to provide an apparatus and method for correctly restoring a defective frame.

It is further another object of the present invention to provide an apparatus and method for providing a moving-image service with high quality even though errors occur in a frame.

In accordance with one aspect of the present invention, there is provided an apparatus for concealing an error in a frame using multiple frames. The apparatus comprises a frame decoder for decoding a bit stream of a received coded frame, and determining whether there is a defective macro block in the decoded frame; a buffer for storing at least two previous frames decoded by the frame decoder, and outputting a decoded current frame according to a control signal; an error corrector for, if there is a defective macro block in the current frame, searching for a candidate macro block most similar to the defective macro block in the current frame from the at least two previous frames stored in the buffer and restoring the defective macro block by applying error variance-based weights to the respective macro blocks; a combining/outputting unit for replacing the defective macro block in the current frame, output from the buffer, with the restored macro block output from the error corrector, and providing a frame; and a controller for controlling an output of the current frame and controlling replacement and combining of the macro block through the buffer, the error corrector, and the combining/outputting unit.

In accordance with another aspect of the present invention, there is provided a method for concealing an error in a frame. The method comprises the steps of decoding a frame received via a communication network, and storing the decoded frame in a buffer as a current frame; if there is a defective macro block in the current frame, searching for pixels of macro blocks adjacent to the defective macro block, and analyzing candidate macro bocks having pixel values most similar to the pixels of the adjacent macro blocks from respective previous frames; calculating weights based on error variances of the candidate macro blocks; extracting a predetermined number of macro blocks from the candidate macro blocks, and restoring the defective macro block using the weights of the extracted macro blocks; and replacing the defective macro block in the current frame with the restored macro block.

### BRIEF DESCRIPTION OF THE DRAWINGS

The above and other objects, features and advantages of the present invention will become more apparent from the following detailed description when taken in conjunction with the accompanying drawings in which:

FIG. 1 is a diagram illustrating a conventional one-frame structure of a frame;

FIG. 2 is a diagram illustrating a method for concealing errors in a received frame using a single frame according to the prior art;

FIG. 3 is a diagram illustrating a method for concealing errors in a received frame using multiple frames according to the prior art;

FIG. 4 is a block diagram illustrating a structure of an apparatus for concealing errors in a frame according to an embodiment of the present invention;

FIG. 5 is a diagram illustrating reference search regions based on which a defective macro block is replaced for comparison between a current frame and previous frames according to an embodiment of the present invention;

FIG. 6 is a diagram illustrating candidate macro blocks in respective previous frames and arrangement of the candidate macro blocks according to an embodiment of the present invention;

FIG. 7 is a flowchart illustrating a procedure for concealing errors in a frame according to an embodiment of the present invention;

FIGS. 8A and 8B illustrate comparative simulation results on performance obtained while changing the number of candidate macro blocks in use among multiple candidate macro blocks; and

FIGS. 9A and 9B illustrate comparative simulation results on the conventional averaging method and the new adaptive weighting method for n=2 (where ‘n’ denotes the number of previous frames).

### DETAILED DESCRIPTION OF THE PREFERRED EMBODIMENTS

Embodiments of the present invention will now be described in detail with reference to the accompanying drawings. In the drawings, the same or similar elements are denoted by the same reference numerals even though they are depicted in different drawings. In the following description, a detailed description of known functions and configurations incorporated herein has been omitted for conciseness.

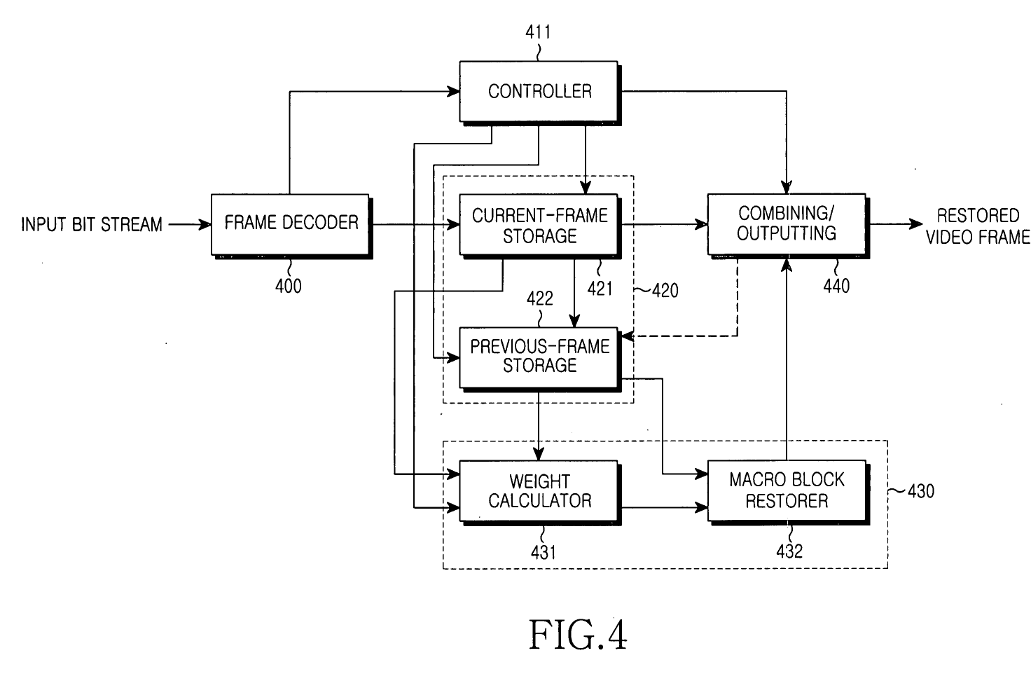

FIG. 4 is a block diagram illustrating a structure of an apparatus for concealing errors in a frame according to an embodiment of the present invention. Referring to FIG. 4, an input bit stream for a signal is input to a frame decoder 400. The frame decoder 400 decodes data of the input bit stream using a decoding scheme corresponding to the coding scheme by which the input bit stream was coded. The coding scheme includes H.263, H.263+, Moving Picture Experts Group 1 (MPEG-1), MPEG-2, MPEG-4, and H.26L coding schemes. The frame decoder 400 performs frame decoding according to the decoding scheme, and outputs the decoded data to a buffer 420.

The buffer 420 comprises a current-frame storage 421 and a previous-frame storage 422. The current-frame storage 421 stores current-frame data received from the frame decoder 400, and the previous-frame storage 422 stores previous-frame data stored in the current-frame storage 421 when the next frame is received. That is, when a new frame data arrives. It is stored in the current-frame storage 421. The data that was previously stored in current-frame storage 421 is then stored in previous-frame storage 422. According to an embodiment of the present invention, the previous-frame storage 422 does not store single-frame data but only multi-frame data. That is, the previous-frame storage 422 stores data of two or more frames.

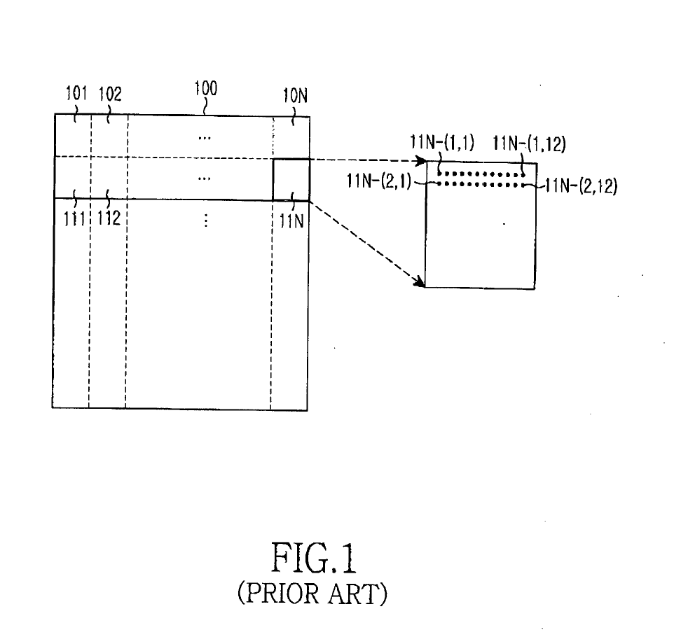

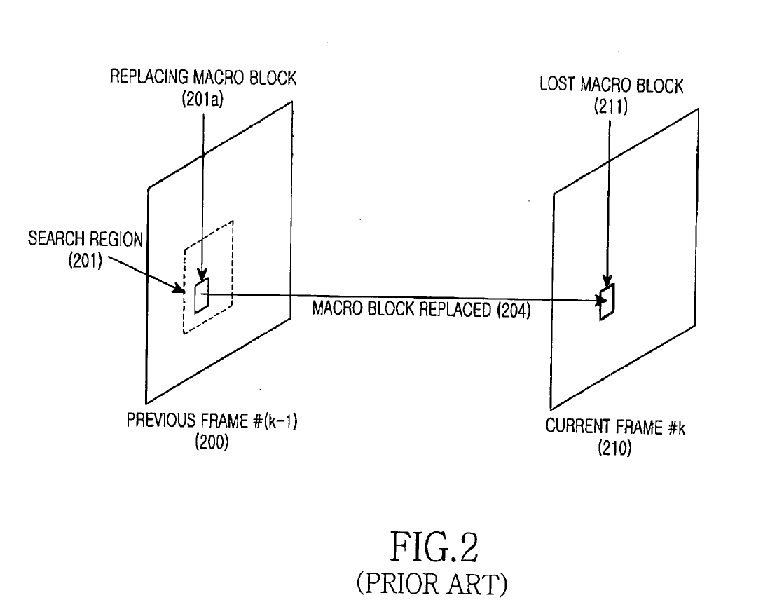

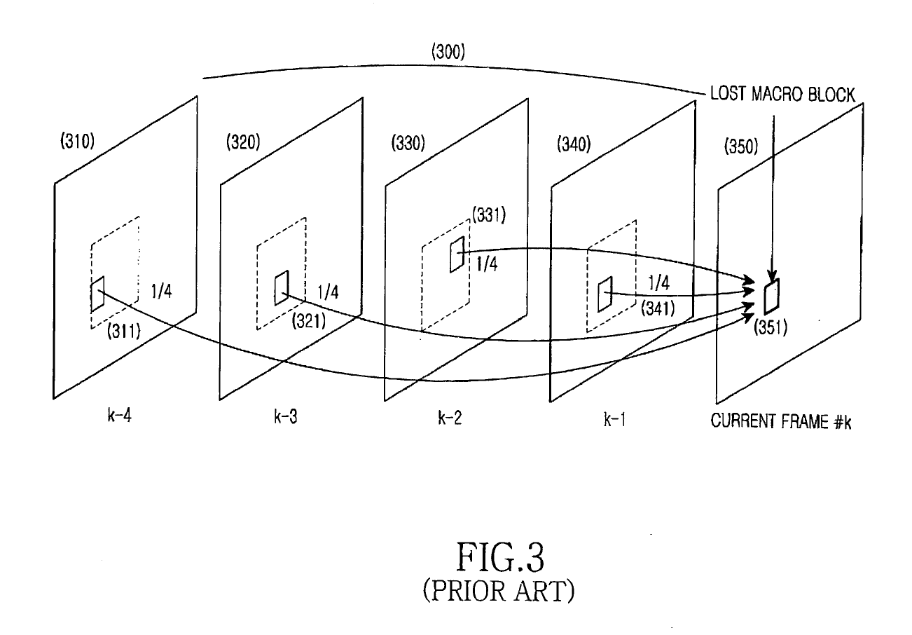

Further, the frame decoder 400 generates an error indication signal based on a result of frame decoding, and outputs the error indication signal to a controller 411. The error indication signal indicates whether an error occurs, by the macro block, as described in connection with FIGS. 1 to 3. Therefore, when one-frame decoding is completed, errors can occur in one or more macro blocks. When errors occur in a specific macro block in this way, the frame decoder 400 provides information on the defective macro block, or errored macro block, to the controller 411.

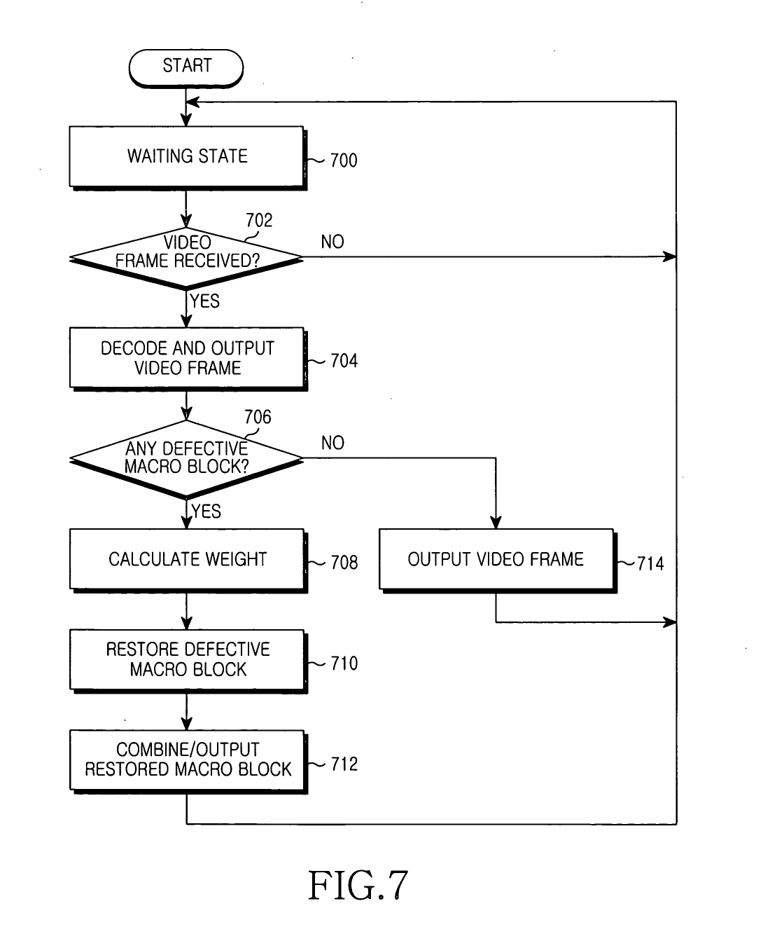

If the controller 411 detects that there is a defective macro block in the frame received from the frame decoder 400, it controls the buffer 420 and an error corrector 430 to generate a macro block most similar to the defective macro block. Further, the controller 411 performs a control operation such that the defective macro block in the current frame is replaced with the generated most similar macro block, thereby generating a restored frame. However, if there is no defective macro block, the controller 411 outputs the received frame without error correction. A detailed operation of the controller 411 will be described with reference to FIG. 7.

The buffer 420, as described above, includes the current-frame storage 421 for storing a currently-received frame and the previous-frame storage 422 for storing two or more previously-received frames. The current-frame storage 421 stores a decoded current frame output from the frame decoder 400, and the previous-frame storage 422 stores previous frames output from the current-frame storage 421. The frames stored in the previous-frame storage 422 are used to conceal a defective macro block, if any.

Also, the previous-frame storage 422 can store a frame including a newly generated or replaced macro block rather than an error-concealed or defective macro block, or store a frame before error correction. Therefore, as illustrated in FIG. 4, the previous-frame storage 422 can selectively store a frame output from the current-frame storage 421 or a frame output from a combining/outputting unit 440.

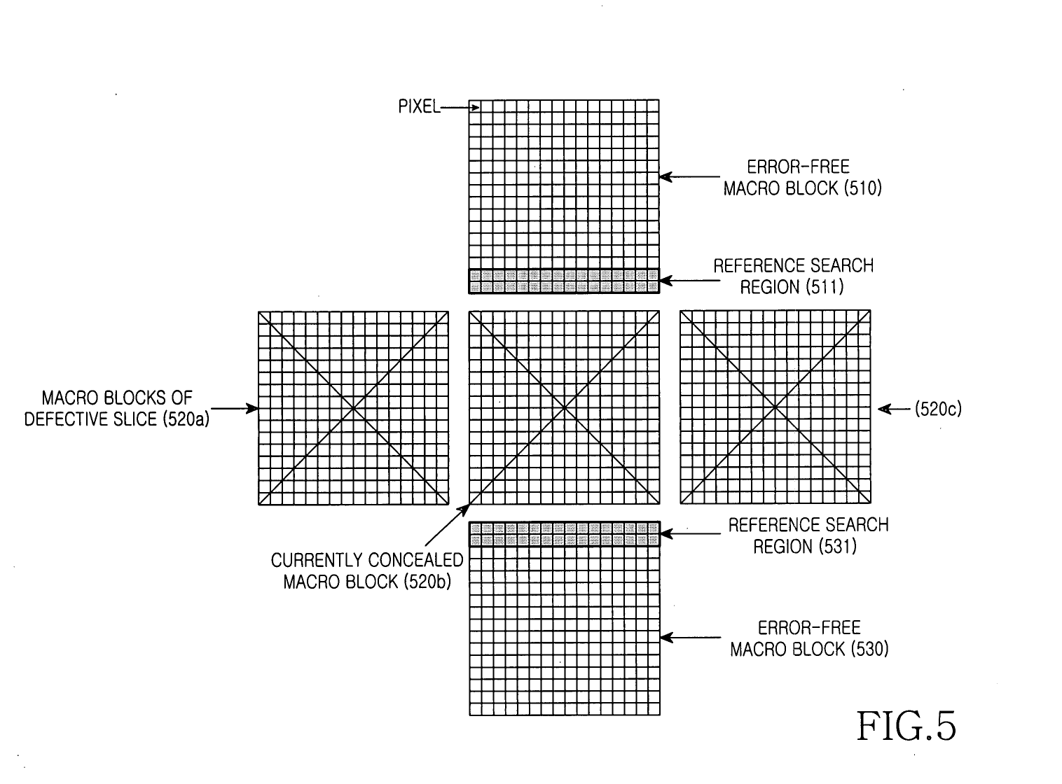

A description will now be made of a weight calculator 431 and a macro block restorer 432 comprising the error corrector 430. If there is a defective macro block in a current frame, the error corrector 430 searches for macro blocks most similar to the defective macro block by comparing the current frame with previous frames, and restores the defective macro block by applying an error variance-based weight to the searched macro blocks of the previous frames. First, the weight calculator 431 will be described herein below with reference to FIG. 5.

FIG. 5 is a diagram illustrating reference search regions based on which a defective macro block is replaced for comparison between a current frame and previous frames according to an embodiment of the present invention. In FIG. 5, a description will be made of a method for concealing errors in a second macro block 520b among defective macro blocks 520a, 520b and 520c included in one frame. The weight calculator 431 uses values of pixels in two adjacent lines in an upper macro block 510 and a lower macro block 530 of the defective macro block 520b.

That is, the weight calculator 431 extracts two-line pixel values from a reference search region 511 adjacent to the defective macro block 520b, located in the error-free upper macro block 510. Further, the weight calculator 431 extracts two-line pixel values from a reference search region 531 adjacent to the defective macro block 520b, located in the error-free lower macro block 530.

The weight calculator 431 compares pixel values extracted from the reference search regions 511 and 513 with internal pixel values of respective previous frames, and searches for macro blocks of previous frames where there is a search region having the most similar pixel values as the reference search regions 511 and 513. The search region of each previous frame, as described above in the Related Art section, is set by defining a particular region in each previous frame, and is used to detect a macro block having the most similar pixel values by comparing pixel values in a corresponding search region with pixel values extracted from the reference search regions.

Alternatively, a macro block having the most similar pixel values as the pixel values extracted from the reference search regions can be searched for in the entire regions of the previous frames. The embodiments of the present invention can selectively use one of the two search methods. No matter which search method the embodiments of the present invention use, the important point is to extract pixel values from two adjacent lines of a defective macro block and compare the extracted pixel values with internal pixel values of error-free macro blocks of the previous frames, thereby searching for a macro block of each previous frame most similar to the defective macro block.

In this method, if there is any error-free macro block among the left and right macro blocks adjacent to a defective macro block in a current frame, the most similar macro block is searched for in each previous frame by extracting pixel values of two lines adjacent to the defective macro block from the error-free macro block.

For convenience, it will be assumed herein that both an upper macro block and a lower macro block are error-free macro blocks. That is, it will be assumed that the most similar macro block of each previous block is searched for by using pixel values of only two lines in the upper and lower macro blocks. In this case, the most similar macro block is searched for by using a sum of differences between pixel values extracted from the reference search region 511 of the upper macro block 510 and the reference search region 531 of the lower macro block 530 and pixel values of each previous frame. In the following description, a sum of differences between pixel values extracted from reference search regions of a current defective frame and pixel values in a previous frame will be referred to as a “sum of absolute difference (SAD).”

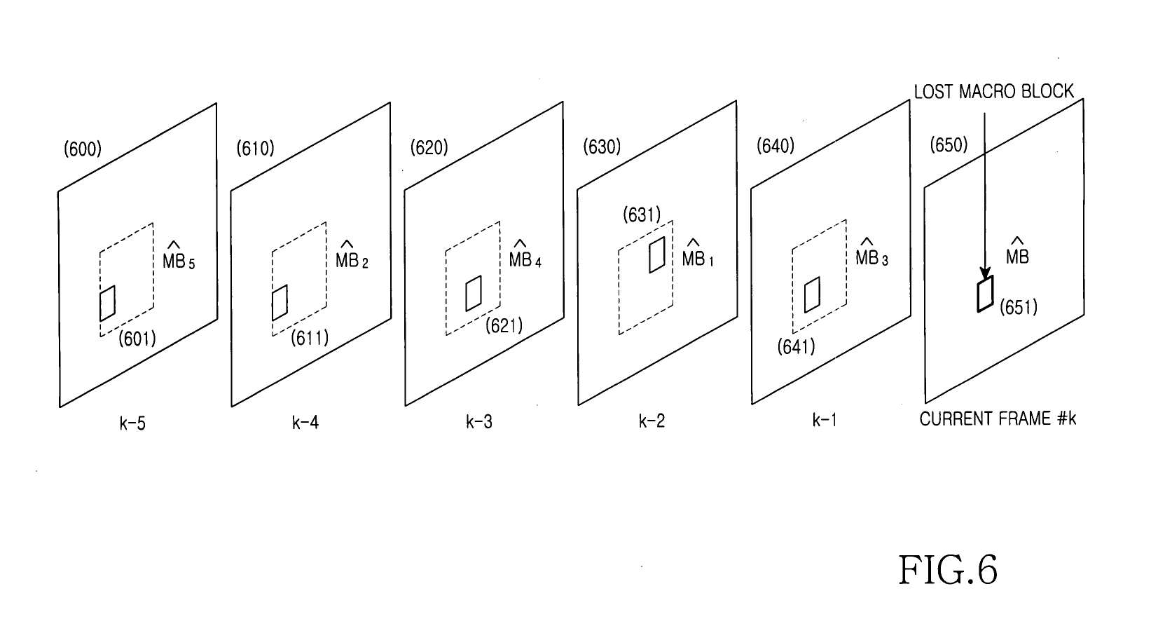

Generally, because moving-image information has a high correlation between a current frame and a previous frame, a previous macro block having a minimum SAD becomes the macro block most similar to a defective macro block in the current frame. In the embodiments of the present invention, because a macro block having the minimum SAD is searched for not in one frame but in two or more frames, a macro block having the minimum SAD can be calculated for each frame. In the following description, a macro block having the minimum SAD regarding a current defective frame will be referred to as a “candidate macro block.” Arrangement of the candidate macro blocks will be described herein below with reference to FIG. 6.

FIG. 6 is a diagram illustrating candidate macro blocks in respective previous frames and arrangement of the candidate macro blocks according to an embodiment of the present invention. It is assumed in FIG. 6 that 5 previous frames are used. The 5 previous frames include a frame 600 at a (k-5)^{th} point, a frame 610 at a (k-4)^{th} point, a frame 620 at a (k-3)^{th} point, a frame 630 at a (k-2)^{th} point, and a frame 640 at a (k-1)^{th} point. In FIG. 6, candidate macro blocks 601, 611, 621, 631 and 641 each having the minimum SAD are located in their corresponding search regions each defined by a dotted line.

The candidate macro blocks \hat{MB}₁˜\hat{MB}₅ of previous frames are arranged in ascending order of SAD. It is assumed in FIG. 6 that a candidate macro block (\hat{MB}₁) 631 of a (k-2)^{th} received frame has the minimum SAD and a candidate macro block (\hat{MB}₅) 601 of a (k-5)^{th} received frame has the maximum SAD.

Therefore, if the candidate macro blocks \hat{MB}₁˜\hat{MB}₅ illustrated in FIG. 6 are arranged in ascending order of SAD, a relationship between the candidate macro blocks \hat{MB}₁˜\hat{MB}₅ is defined as
SADₖ₋₂≦SADₖ₋₄≦SADₖ₋₁≦SADₖ₋₃≦SADₖ₋₅ (1)

If it is assumed that the candidate macro blocks have the relationship defined in Equation (1), a restored macro block \hat{MB} replacing the defective macro block in the current frame #k is calculated by

$$\hat{MB} = {\sum }_{k = 1}^{n} {w}_{k} \cdot {\hat{MB}}_{k} \qquad ( 2 )$$

In Equation (2), ‘n’ denotes the number of previous frames, \hat{MB}ₖ denotes a candidate macro block of a k^{th} frame, and wₖ denotes a weight multiplied by a macro block of a k^{th} frame.

Therefore, Equation (2) calculates a sum of values determined by multiplying candidate macro blocks by corresponding weights when decoding the defective macro block. In Equation (2), the weight wₖ is calculated by

$${ω}_{k} = ( \frac{{\sum }_{i = 1}^{n} ( {σ}_{l}^{2} ) - {σ}_{k}^{2}}{{\sum }_{i = 1}^{n} {σ}_{l}^{2}} ) \times \frac{1}{n - 1} \qquad ( 3 )$$

where (2≦n≦5, Σwₖ =1), and for n=1, \hat{MB}=\hat{MB}₁.

In Equation (3), σ₁² denotes an error variance of a search region in an 1^{th} frame. That is, the σ₁² has the meaning of a SAD described in embodiments of the present invention. Therefore, Equation (3) calculates a value determined by dividing a value obtained by subtracting a corresponding variance from the total variance by the total variance. Specifically, Equation (3) calculates a value determined by multiplying a ratio of an error except a corresponding error to the total error by a corresponding macro block.

A restored macro block generated to conceal a defective macro block in the current frame in the above-stated manner using, for example, 2 candidate macro blocks among the candidate macro blocks can be calculated by Equation (4) in accordance with Equations (2) and Equation (3).

$$\begin{matrix}\hat{MB} = {ω}_{1} \cdot {\hat{MB}}_{1} + {ω}_{2} \cdot {\hat{MB}}_{2} \\ {ω}_{1} = ( \frac{{σ}_{2}^{2}}{{σ}_{1}^{2} + {σ}_{2}^{2}} ) , {ω}_{2} = ( \frac{{σ}_{1}^{2}}{{σ}_{1}^{2} + {σ}_{2}^{2}} )\end{matrix} \qquad ( 4 )$$

In Equation (4), \hat{MB}₁ is weighted in a ratio of an error variance of \hat{MB}₂ to the total error variance. As an error variance value of \hat{MB}₂ is larger, \hat{MB}₁ is multiplied by a larger weight. Therefore, a restored macro block \hat{MB} is greatly affected by \hat{MB}₁ rather than \hat{MB}₂. This method proposed in an embodiment of the he present invention is superior in image quality to the conventional method in which an average of pixel values is calculated. A macro block is restored through calculation of Equation (4).

The weights described above are calculated by the weight calculator 431 of FIG. 4, and the calculated weights are input to the macro block restorer 432. The macro block restorer 432 calculates a macro block for replacing the defective macro block using the input weights, and outputs a restored macro block.

The restored macro block output from the macro block restorer 432 is input to the combining/outputting unit 440. The combining/outputting unit 440, under the control of the controller 411, replaces the defective macro block in the current frame stored in the current-frame storage 421 with the restored macro block output from the macro block restorer 432, thereby outputting a frame with an error-concealed defective macro block.

The foregoing process will now be described with reference to FIG. 7. FIG. 7 is a flowchart illustrating a procedure for concealing errors in a frame according to an embodiment of the present invention. Referring to FIG. 7, in step 700, the controller 411 maintains a waiting state. The “waiting state” refers to a state in which the controller 411 waits for a frame. Generally, when a bit stream is input, there is no waiting state. However, for convenience, a state before an initial frame is input will be defined as a waiting state. In the waiting state, the controller 411 proceeds to step 702 where it determines whether a frame is received.

If it is determined in step 702 that a frame is received, the controller 411 proceeds to step 704. If a frame is not received, the controller 411, maintains the waiting state in step 700. In step 704, the controller 411 controls the frame decoder 400 to decode the received frame according to a predetermined decoding scheme and to output the decoded frame to the current-frame storage 421 in the buffer 420. In step 706, the controller 411 determines whether a defective macro block is generated from the frame decoder 400.

The controller 411 outputs a signal indicating the occurrence of a defective macro block each time the frame decoder 400 generates the defective macro block, and the controller 411 also indicates a position of the defective macro block. If it is determined in step 706 that a defective macro block is generated from the frame decoder 400, the controller 411 proceeds to step 708 where it calculates a weight for restoring the defective macro block, otherwise, the controller 411 proceeds to step 714. In step 714, the controller 411 performs a control operation such that a frame stored in the current-frame storage 421 is output to the combining/outputting unit 440.

In step 708, the controller 411 stores the received frame in the current-frame storage 421 for a restoration time and then outputs the stored frame to the combining/outputting unit 440 at a predetermined time. While a frame is output in step 714, the frame stored in the current-frame storage 421 or the frame output through the combining/outputting unit 440 is shifted to the previous-frame storage 422. The frame storages 421 and 422 can be implemented with a shift buffer. In the case where the frame storages 421 and 422 are implemented with a shift buffer capable of storing a unit frame, when a next frame is stored while the current frame is output, the output frame is shifted to and stored in the previous-frame storage 422 as a previous frame.

If a frame is output through the combining/outputting unit 440, the controller 411 returns to step 702. Generally, because frames are continuously received, the controller 411 immediately proceeds to step 704. In the meantime, if it is determined in step 706 that there is a defective macro block in the received frame, the controller 411 stores the received frame in the current-frame storage 421. Thereafter, in step 708, the controller 411 calculates a weight for restoring the defective macro block from two or more previous frames.

The weight, as described above, is calculated by setting up a reference search region of a defective macro block in a current frame, setting up search regions of neighboring macro blocks, searching for candidate macro blocks having a minimum SAD in a reference search region of the current frame and search regions of respective previous frames, and then arranging the candidate macro blocks in ascending order of SAD considering the error variance shown in Equation (3).

After searching for candidate macro blocks having a minimum SAD in respective previous frames and calculating a weight of each candidate macro block, the controller 411 restores, in step 710, the defective macro block by controlling the macro block restorer 432. The defective macro block is restored by arranging the candidate macro blocks having the minimum SAD in ascending order of SAD, calculating weights to be applied to the candidate macro blocks according to the number of the candidate macro blocks, and then summing the weights.

In step 712, the controller 411, after restoration of the defective macro block, outputs the macro block generated by the macro block restorer 432 to the combining/outputting unit 440. At the same time, the controller 411 outputs the frame stored in the current-frame storage 421 to the combining/outputting unit 440. Thereafter, the controller 411 replaces the defective macro block in the currently-received frame with the macro block generated by the macro block restorer 432, thereby forming a completed frame, and then outputs the frame. In this manner, it is possible to conceal a defective macro block in a frame.

A description will now be made of results on simulations performed based on H.26L JM 2.0 using the method proposed in the an embodiment of the present invention.

H.26L has various options, and the following environments were used for the simulations. Universal variable length coding (UVLC) is chosen, and a compensation resolution of a motion vector is set to ¼-pixel accuracy. Further, the number of reference frames is set to 5, and a type of coded frames is set to an IPPP type. The simulations were performed with two Quarter Common Intermediate Format (QCIF) images of a Foreman image and a Carphone image.

Generally, in moving-image coding at a low transfer rate, two-frame concealment is commonly used for bandwidth reduction. In order to increase the applicability of the error detection procedure, in an embodiment of the present invention the frame rate of an original image is adjusted from 30 frames/sec to 10 frames/sec. A quantization coefficient is set to 15 for an intra-frame, and to 16 for an inter-frame. Under such options, the Foreman image was coded at 93.4 Kbps, and the Carphone image was coded at 89.6 Kbps. A slice loss rate (SLR) is set to 0.01, 0.02, 0.03; 0.04, 0.05, 0.07 and 0.1. After 20 different error models were applied to each SLR, and the final image quality was evaluated through comparison between averages of picture signal-to-noise ratios (PSNRs).

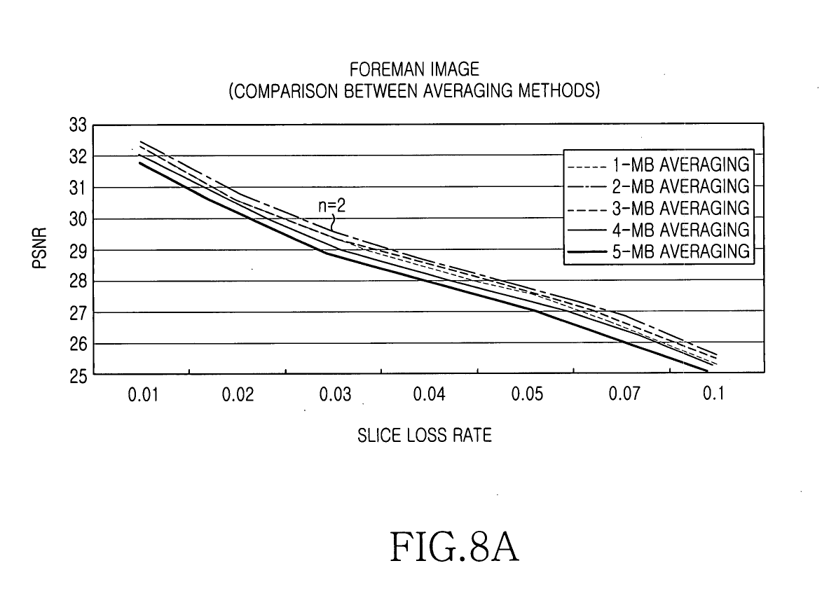

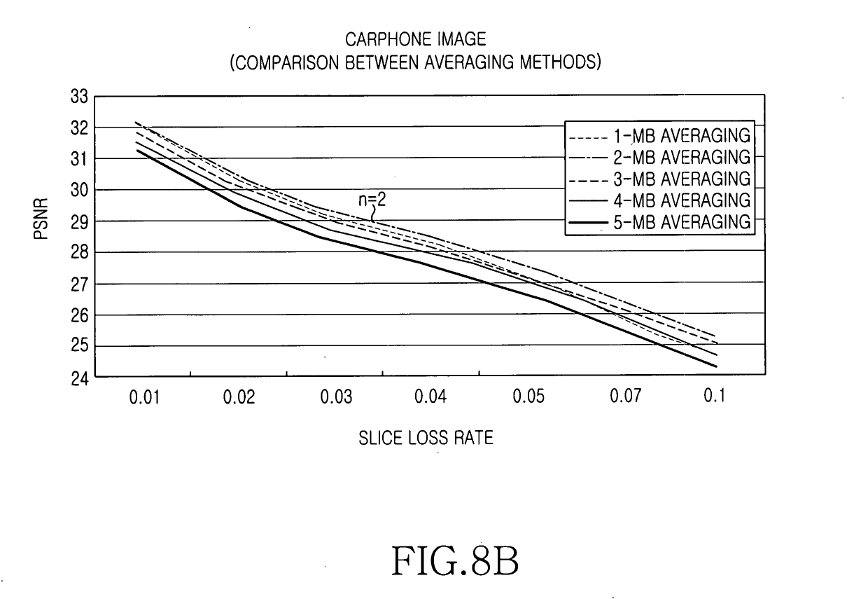

FIGS. 8A and 8B illustrate comparative simulation results on performance obtained while changing the number of candidate macro blocks in use among multiple candidate macro blocks. FIGS. 8A and 8B illustrate simulations on a Foreman image and a Carphone image, respectively. It can be understood from FIGS. 8A and 8B that both cases show highest performance for n=2 (where ‘n’ denotes the number of previous frames). That is, it can be noted that the best image quality is obtained on average when only two candidate macro blocks are selected from multiple candidate macro blocks.

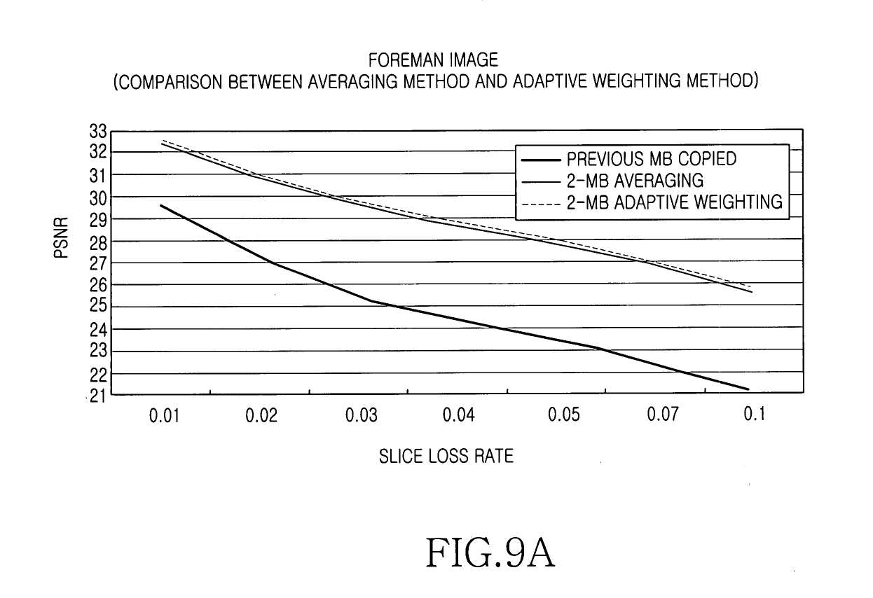

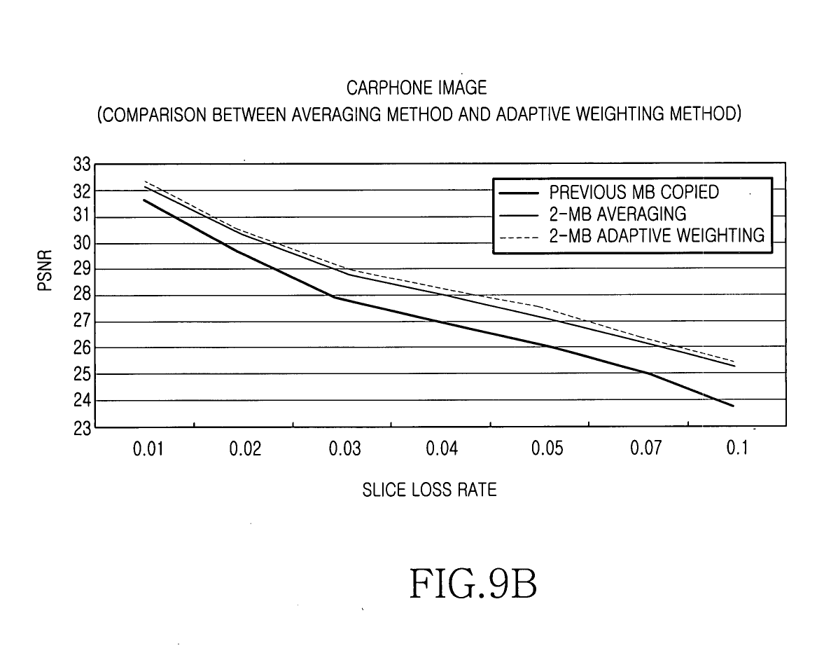

FIGS. 9A and 9B illustrate comparative simulation results using the conventional averaging method and the new adaptive weighting method for n=2. It can be understood from FIGS. 9A and 9B that the new adaptive weighting method is superior to the conventional averaging method in PSNR at every SLR. Therefore, the new adaptive weighting method can provide a high-quality service to users by performing high-performance frame error concealment.

As can be understood from the foregoing description, when an error occurs in a frame, weights based on an error variance, i.e., based on a correlation between a defective macro block and an original macro block, are calculated using only several optimal candidate macro blocks among multiple candidate macro blocks and then summed, thereby securing high image restoration capability. In addition, when applied to H.26L which is expected to be popular in the future, the new multi-frame error concealment method can be implemented using the existing frame decoder without modification.

While the invention has been shown and described with reference to certain embodiments thereof, it should be understood by those skilled in the art that various changes in form and details may be made therein without departing from the spirit and scope of the invention as defined by the appended claims.

1. An apparatus for concealing an error in a frame using multiple frames, the apparatus comprising:
a frame decoder for decoding a bit stream of a received coded frame, and determining whether there is a defective macro block in the decoded frame;
a buffer for storing at least two previous frames decoded by the frame decoder, and outputting a decoded current frame according to a control signal;
an error corrector for, if there is a defective macro block in the current frame, searching for a candidate macro block most similar to the defective macro block in the current frame from the at least two previous frames stored in the buffer and restoring the defective macro block by applying error variance-based weights to the respective macro blocks;
a combining/outputting unit for replacing the defective macro block in the current frame, output from the buffer, with the restored macro block output from the error corrector, and providing a frame; and
a controller for controlling output of the current frame and controlling replacement and combining of the macro block through the buffer, the error corrector, and the combining/outputting unit.

2. The apparatus of claim 1, wherein the buffer comprises:
a current-frame storage for storing the current frame received from the frame decoder; and
a previous-frame storage for storing the previous frames.

3. The apparatus of claim 1, wherein the error corrector comprises:
a weight calculator for analyzing pixels of macro blocks adjacent to the defective macro block in the current frame, analyzing candidate macro blocks having pixels most similar to the pixels of the adjacent macro blocks in search regions of the respective previous frames, and calculating the weights for the respective candidate macro blocks; and
a macro block restorer for generating the restored macro block by applying the weights to a predetermined number of the candidate macro blocks from the most similar macro blocks among the candidate macro blocks.

4. The apparatus of claim 3, wherein at least two-line pixels are used as the pixels of the macro blocks adjacent to the defective macro block in the current frame.

5. The apparatus of claim 1, wherein the weight is determined by
$${ω}_{k} = ( \frac{{\sum }_{i = 1}^{n} ( {σ}_{l}^{2} ) - {σ}_{k}^{2}}{{\sum }_{i = 1}^{n} {σ}_{l}^{2}} ) \times \frac{1}{n - 1}$$
where ‘n’ denotes the number of previous frames, σ₁² denotes an error variance of a search region in an 1^{th} frame, σₖ² denotes an error variance of a search region in a k^{th} frame, and wₖ denotes a weight multiplied by a macro block of a k^{th} frame.

6. The apparatus of claim 1, wherein similarity between the defective macro block and the candidate macro blocks is determined in ascending order of a sum of an absolute difference (SAD) between pixel values of a reference search region in the defective macro block and pixel values of search regions in the respective candidate macro blocks.

7. A method for concealing an error in a frame, the method comprising the steps of:
decoding a frame received via a communication network, and storing the decoded frame in a buffer as a current frame;
if there is a defective macro block in the current frame, searching for pixels of macro blocks adjacent to the defective macro block, and analyzing candidate macro bocks having pixel values most similar to the pixels of the adjacent macro blocks from respective previous frames;
calculating weights based on error variances of the candidate macro blocks;
extracting a predetermined number of macro blocks from the candidate macro blocks, and restoring the defective macro block using the weights of the extracted macro blocks; and
replacing the defective macro block in the current frame with the restored macro block.

8. The method of claim 7, wherein in the analysis step, at least two-line pixels are used as the pixels of the macro blocks adjacent to the defective macro block in the current frame.

9. The method of claim 7, wherein the weight is determined by
$${ω}_{k} = ( \frac{{\sum }_{i = 1}^{n} ( {σ}_{l}^{2} ) - {σ}_{k}^{2}}{{\sum }_{i = 1}^{n} {σ}_{l}^{2}} ) \times \frac{1}{n - 1}$$
where ‘n’ denotes the number of previous frames, σ₁² denotes an error variance of a search region in an 1^{th} frame, σₖ² denotes an error variance of a search region in a k^{th} frame, and wₖ denotes a weight multiplied by a macro block of a k^{th} frame.

10. The method of claim 9, wherein the error variance is equivalent to a sum of an absolute difference (SAD) between pixels of a macro block adjacent to the defective macro block and pixel values of a search region in the previous frame.

11. The method of claim 7, further comprising the step of outputting the current frame without error correction if there is no defective macro block in the current frame.

12. The method of claim 7, wherein the similarity between the defective macro block and the candidate macro blocks is determined in ascending order of a sum of an absolute difference (SAD) between pixel values of a reference search region in the defective macro block and pixel values of search regions in the respective candidate macro blocks.

13. The method of claim 12, wherein the number of candidate macro blocks having high similarity is larger than or equal to 2.

14. The method of claim 7, wherein the step of restoring the defective macro block comprises the step of applying the weights to the candidate macro blocks and then calculating a sum thereof, thereby restoring the defective macro block.
